(19) United States
(12) Patent Application Publication
(10) Pub. No.: US 2025/0062132 A1
(43) Pub. Date: Feb. 20, 2025

(54) Etching method of semiconductor structure

(71) Applicant: United Semiconductor (Xiamen) Co., Ltd., Xiamen (CN)

(72) Inventors: Yanjie Liu, Shamen City (CN); Bing Du, Xiamen (CN); LaiJiao Liu, Shamen City (CN); Hailong Gu, Singapore (SG); Chin-Chun Huang, Hsinchu County (TW); Wen Yi Tan, Xiamen (CN)

(73) Assignee: United Semiconductor (Xiamen) Co., Ltd., Xiamen (CN)

(21) Appl. No.: 18/368,025

(22) Filed: Sep. 14, 2023

(30) Foreign Application Priority Data
Aug. 14, 2023 (CN) 202311017655.5

(51) Int. Cl. H01L 21/311; H01L 21/8238

(52) U.S. Cl. CPC H01L 21/31111; H01L 21/823814; H01L 21/823864

(57) ABSTRACT

The invention provides an etching method of a semiconductor structure, which comprises providing a substrate with a gate structure, an oxide layer and a first nitride layer beside the gate structure, and performing an etching step to remove the first nitride layer and keep the oxide layer, wherein in the etching step, the etching selectivity ratio of the etched nitride material to the etched oxide material is greater than 300.

### BACKGROUND OF THE INVENTION

### 1. Field of the Invention

The invention relates to the field of semiconductor process, in particular to an etching method of semiconductor spacers, which has the advantage of saving process steps.

### 2. Description of the Prior Art

Etching step is a common technology in semiconductor manufacturing process, which is generally used to remove various material layers, and can be used to form patterned material layers or as a cleaning step. The quality of etching also directly affects the yield of semiconductor components.

When etching the stacked structure of multiple material layers, it is necessary to adjust the etching selectivity of the etching step. Specifically, when two or more different material layers are stacked and one of them needs to be removed, the etching step can completely remove the required one material without destroying the other material in an ideal situation. Therefore, the preparation of etching liquid is also one of the research directions of etching step. However, the existing etching liquid is limited by the characteristics of its own material, so the etching step still cannot reach the ideal situation.

### SUMMARY OF THE INVENTION

The invention provides an etching method of a semiconductor structure, which comprises providing a substrate with a gate structure, an oxide layer and a first nitride layer disposed beside the gate structure, and performing an etching step to remove the first nitride layer and keep the oxide layer, wherein in the etching step, the etching selectivity ratio of etching a nitride material to etching an oxide material is greater than 300.

The invention is characterized by providing an etching method for improving the existing semiconductor structure, especially for the spacer of different gate structures (such as PMOS and NMOS respectively) after the epitaxial layer is formed. In some technologies, dummy spacers are formed to protect the substrate surface in order to avoid damaging the substrate surface when etching the spacers. However, this method has many steps, which is not conducive to simplifying the process. In the invention, by adjusting the etching process and deliberately reducing the etching rate of the oxide material, the etching selectivity ratio for etching the nitride material to the oxide material is increased, so that the step of forming dummy spacers can be omitted and the etching damage to the substrate can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 4 illustrate an etching method of a semiconductor structure according to a first embodiment of the present invention.

FIGS. 5 to 6 illustrate an etching method of a semiconductor structure according to a second embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Please refer to FIG. 1 to FIG. 4, which illustrate the etching method of the semiconductor structure in the first embodiment of the present invention. First, as shown in FIG. 1, a substrate 10 is provided, which includes two adjacent gate structures of different types, such as NMOS gate 12A and PMOS gate 12B. The NMOS gate 12A and the PMOS gate 12B each include a gate oxide layer 14, a gate conductive layer 16, a first silicon nitride layer 18, a mask layer 20 and a second silicon nitride layer 22. The gate oxide layer 14 is made of silicon oxide and has a U-shaped cross-sectional structure. The gate oxide layer 14 is divided into a bottom surface portion 14A and two sidewall portions 14B, which are actually formed at different steps. Specifically, the bottom surface portion 14A of the gate oxide layer 14 extending in the horizontal direction is formed before the gate conductive layer 16 is formed. The sidewall portions 14B of the gate oxide layer 14 extending in the vertical direction are formed on the sidewall of the gate conductive layer 16 by an oxidation step after the gate conductive layer 16 is formed and patterned, that is, the sidewall portion 14B of the gate oxide layer 14 described here.

The material of the gate conductive layer 16 is, for example, polysilicon, but not limited thereto. The gate conductive layer 16 is located on the gate oxide layer 14, and the bottom surface and two sidewalls of the gate conductive layer 16 directly contact the gate oxide layer 14. The first silicon nitride layer 18 is located on both sides of the gate oxide layer 14 and directly contacts the gate oxide layer 14. The material of the first silicon nitride layer 18 includes silicon nitride. The mask layer 20 is located on top of the gate conductive layer 16, and the material is preferably silicon nitride. It should be noted that the thickness of the mask layer 20 contained in the NMOS gate 12A and the PMOS gate 12B may be different, specifically, the thickness of the mask layer 20 contained in the NMOS gate 12A is greater than that contained in the PMOS gate 12B. The second silicon nitride layer 22 is located outside the first silicon nitride layer 18 and made of silicon nitride. It is worth noting that the second silicon nitride layer 22 contained in NMOS gate 12A and PMOS gate 12B may have different shapes. Specifically, the second silicon nitride layer 22 contained in NMOS gate 12A covers the top surface and side of substrate 10, first silicon nitride layer 18 and mask layer 20, while the second silicon nitride layer 22 contained in PMOS gate 12B only covers substrate 10 and first silicon nitride layer 18, but does not cover the top surface and side of mask layer 20.

In addition, the substrate 10 also includes a shallow trench isolation STI located outside and surrounding the transistor. After the transistor is formed on the substrate 10, an epitaxial layer EPI will be formed in the substrate, in which the epitaxial layer is made of silicon germanium (SiGe), for example, but not limited to this. It is worth noting that in the process of forming the epitaxial layer EPI, the second silicon nitride layer 22 is used as a mask layer, and an etching step (not shown) is performed to etch the substrate 10 next to the PMOS gate 12B into a groove, and then the epitaxial layer EPI is formed in the groove, as shown in FIG. 1. The epitaxial layer EPI can be doped with specific ions in the subsequent step to be used as the source/drain of the transistor.

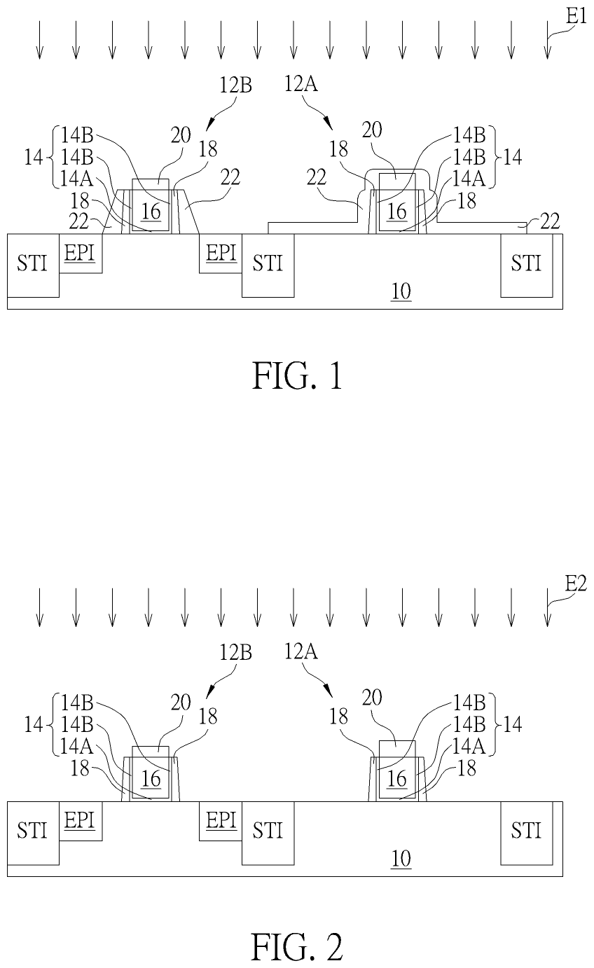

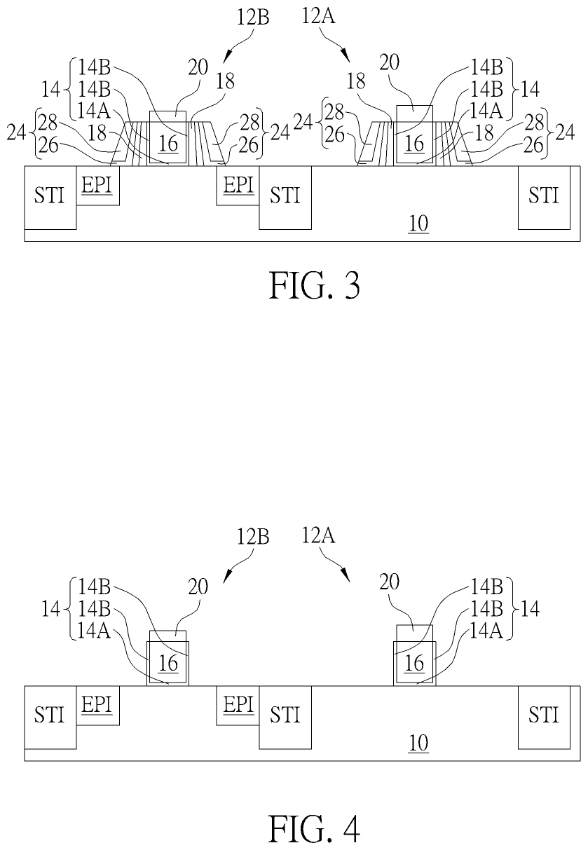

After the epitaxial layer EPI is formed, as shown in FIG. 2, an etching step E1 is performed to remove the second silicon nitride layer 22, wherein the methods for removing the second silicon nitride layer 22 include but are not limited to dry etching or wet etching, and the present invention is not limited to this. Next, the first silicon nitride layer 18 and the mask layer 20 need to be removed by etching in the subsequent steps, so as to perform subsequent steps such as ion doping. However, according to the experiments of the applicant, if the first silicon nitride layer 18 and the mask layer 20 are directly removed by etching, the surface of the substrate 10 and the gate oxide layer 14 may be damaged at the same time. Therefore, as shown in FIG. 3, before removing the first silicon nitride layer 18 and the mask layer 20 by etching, it is necessary to form dummy spacers 24 on both sides of the second silicon nitride layer 22 included in the NMOS gate 12A and the PMOS gate 12B respectively. The dummy spacer 24 further comprises an oxide layer 26 and a nitride layer 28, wherein the oxide layer 26 is made of silicon oxide and preferably has an L-shaped cross-sectional profile, and the nitride layer 28 is made of silicon nitride and is located on the oxide layer 26 and has a sail-like profile.

The purpose of forming the dummy spacer 24 is to avoid damaging the surface of the substrate 10 and the gate oxide layer 14 during the etching process, so the dummy spacers 24 are formed first to protect them. Next, the structure shown in FIG. 3 is subjected to one or more etching steps E2 to remove the dummy spacers 24, the mask layer 20 and the first silicon nitride layer 18 in sequence. After the etching step E2 is completed, the structure is shown in FIG. 4, leaving the gate oxide layer 14 and the gate conductive layer 16 on the substrate 10, and the remaining spacers have been removed. In the following steps, it is possible to re-form new spacers on the side of the gate structure, or to dope the epitaxial layer EPI, etc. These steps belong to the known technology in this field, so they are not described here.

The applicant found that the above steps still have the possibility of improvement, because the above steps need to form the dummy spacers 24 first and then remove them, and there are many etching steps, which is not conducive to the simplification of the process. After observation, the applicant found that the surface of the substrate 10 was still damaged to a certain extent after etching in the above steps. For example, the applicant observed that the surface of the substrate 10 decreased by about 43 angstroms compared with that before etching. However, if the above step of forming dummy spacers 24 is omitted and the mask layer 20 and the first silicon nitride layer 18 are directly removed by etching step E1, it is found that the surface damage to the substrate 10 is greater.

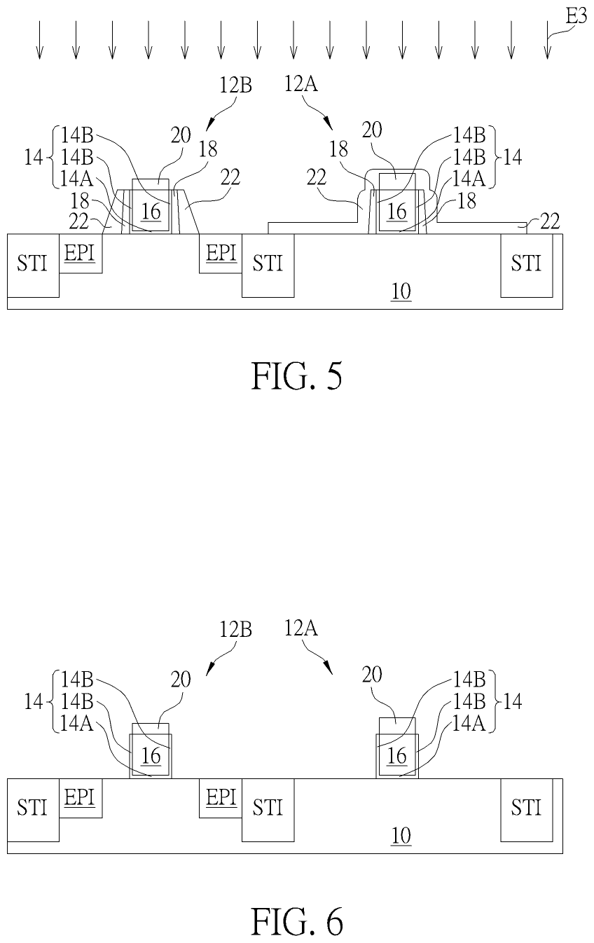

In order to improve the process quality and reduce the damage to the surface caused by the etching step, the second embodiment of the present invention provides an improved etching method of a semiconductor structure. Please refer to FIGS. 5 and 6, which illustrate the etching method of the semiconductor structure in the second embodiment of the present invention. In this embodiment, similar to the structure in FIG. 1, it also includes a substrate 10, on which there are two adjacent gate structures of different types, such as NMOS gate 12A and PMOS gate 12B. The NMOS gate 12A and the PMOS gate 12B each include a gate oxide layer 14, a gate conductive layer 16, a first silicon nitride layer 18, a mask layer 20 and a second silicon nitride layer 22. These structures have been introduced in the above paragraphs, and they are not repeated here.

Different from the above embodiment, as shown in FIG. 5, in this embodiment, only a single etching step E3 is performed to remove the first silicon nitride layer 18, the mask layer 20 and the second silicon nitride layer 22, thus forming the structure of FIG. 6 (like the structure of FIG. 4 in the above embodiment). It is worth noting that the etching step E3 of this embodiment is different from the etching step E1 and the etching step E2 mentioned above. Specifically, the selectivity ratio of the etching rate for etching the silicon nitride material to the etching rate for etching the silicon oxide material in the etching step E3 (hereinafter referred to as the etching selectivity ratio) is greater than 300. Compared with the etching step E3, the etching selectivity ratio of the etching step E1 to the etching step E2 is less than 50.

More specifically, in the etching step E3 of this embodiment, hot phosphoric acid is used as the etching solution, and the substrate and the material layer are immersed in the hot phosphoric acid for etching. The difference from the first embodiment is that the etching selectivity in the etching step E3 of this embodiment is greater than 300 because the etching rate for etching the silicon oxide material is reduced, rather than the etching rate for etching the silicon nitride material is increased, thereby increasing the etching selectivity ratio.

Furthermore, in the etching step E3 of this embodiment, the silicic acid component contained therein is increased, so that the silicic acid concentration is controlled above 3.5 ppm of the whole hot phosphoric acid solution. Compared with this embodiment, the concentration of silicic acid contained in the hot phosphoric acid solution in the etching step E1 or the etching step E2 in the first embodiment is about 2 ppm or less. According to the experimental results of the applicant, comparing this embodiment with the above-mentioned first embodiment, in the etching step E1, the etching rate for etching the silicon oxide material with solution is about 0.189 angstrom per minute, and the etching rate for etching the silicon nitride material is about 9.7 angstrom per minute, so the etching selectivity ratio is about 51. In the etching step E2, the etching rate for etching the silicon oxide material is about 1.4 angstroms per minute, the etching rate for etching the silicon nitride material is about 45 angstroms per minute, so the etching selectivity ratio is about 32. In the etching step E3, the etching rate for etching the silicon oxide material is about 0.13 angstrom per minute, the etching rate for etching the silicon nitride material is about 45 angstrom per minute, so the etching selectivity ratio is about 346. It can be seen that after increasing the concentration of silicic acid in the etching solution, the etching rate for etching the silicon oxide material in the etching step E3 is obviously decreased, and then the etching selectivity is increased by at least 300.

The applicant found that the etching step E3 has a higher etching selectivity than the etching step E1 and the etching step E2, and the structure in FIG. 5 can be directly etched into the structure as shown in FIG. 6 by performing the etching step E3 with a solution with a high etching selectivity, that is to say, the steps of forming dummy spacers can be omitted, which effectively reduces the process steps. In addition, the applicant observed the structure shown in FIG. 6, after the completion of the etching step E3, the damage to the surface of the substrate 10 was also small. According to the applicant's experimental results, the surface of the substrate drops by about 26 Angstroms after the etching step E3. However, in the first embodiment mentioned above, the drop is about 43 Angstroms, so this embodiment has less damage to the surface of the substrate 10.

It is worth noting that, compared with the above-mentioned first embodiment, this embodiment has changed the parameters of the etching process to increase the etching selectivity to more than 300, but this change cannot be achieved by simply adjusting the etching parameters. As mentioned above, hot phosphoric acid has an limit on the rate of etching the silicon nitride, and even if the acid concentration is increased, the rate of dissolving silicon nitride cannot be increased. However, the concentration of dissolved silicic acid in hot phosphoric acid solution has a certain upper limit, and silicic acid will start to precipitate when the concentration exceeds about 4 ppm, and the concentration of silicic acid contained in hot phosphoric acid will gradually increase after the hot phosphoric acid etches materials such as silicon wafers. Therefore, both the etching step E1 and the etching step E2 used in the first embodiment of the present invention maintain the silicic acid concentration in a moderate range (about 2 ppm), so as to prevent the silicic acid concentration from being precipitated during the etching process, but at the same time, the etching selectivity of the etching solution cannot be improved at this silicic acid concentration.

In the second embodiment of the present invention, the concentration of silicic acid in hot phosphoric acid is increased to be close to the critical value (upper limit) of precipitation, that is, above 3.5 ppm. As the concentration of silicic acid gradually increases, the etching rate for etching the silicon oxide material gradually decreases. Therefore, the etching step E3 can quickly etch the silicon nitride material and reduce the damage to the silicon oxide material as much as possible. As shown in FIG. 5, the materials of the first silicon nitride layer 18, the mask layer 20 and the second silicon nitride layer 22 outside or above the gate conductive layer 16 are all silicon nitride, and only the gate oxide layer 14 below and on the sidewall of the gate conductive layer 16 is silicon oxide. Therefore, the first silicon nitride layer 18, the mask layer 20 and the second silicon nitride layer 22 can be quickly removed by using the high etching selectivity of the etching step E3, and the gate oxide layer 14 can be used as the material layer for protecting the gate conductive layer 16. Compared with the first embodiment, since the etching time is shorter and the etching times are reduced, the damage to the surface of the substrate 10 can also be reduced.

It is worth noting that in the first embodiment, the concentration of silicic acid in hot phosphoric acid solution is controlled within 2 ppm, because there is still a distance from the concentration of precipitated acid, so it is not necessary to change new etching solution frequently. Compared with the first embodiment, the etching solution in the second embodiment has the advantage of high etching selectivity, but its silicic acid concentration is close to the critical value of precipitation, therefore, after a period of use, it is necessary to filter out the precipitated silicic acid deposits and replenish the etching solution to maintain the concentration of silicic acid in the etching solution in the second embodiment within a certain range (that is, close to the critical value of precipitation but not exceeding the critical value of precipitation).

Based on the above description and drawings, the present invention provides an etching method of a semiconductor structure, which includes providing a substrate 10, which includes a gate structure (such as a gate conductive layer 16 in an NMOS gate 12A), an oxide layer 14 and a first nitride layer 18 disposed beside the gate structure 16, and performing an etching step E3 to remove the first nitride layer 18 and keep the oxide layer 14, wherein in the etching step E3, the etching selectivity ratio of etching a nitride material to etching an oxide material is greater than 300.

In some embodiments of the present invention, the oxide layer 14 has a U-shaped cross section and is located at the bottom and two sidewalls of the gate structure 16.

In some embodiments of the present invention, a mask layer 20 is formed on the top surface of the gate structure 16.

In some embodiments of the present invention, a second nitride layer 22 is formed to cover the outer sidewall of the first nitride layer 18, part of the surface of the substrate 10, and the top surface and sidewall of the mask layer 20.

In some embodiments of the present invention, the first nitride layer 18, the second nitride layer 22 and the mask layer 20 are all removed in the etching step E3.

In some embodiments of the present invention, after the formation of the second oxide layer 22 until the etching step E3, no other spacers composed of oxide layers or nitride layers are formed.

In some embodiments of the present invention, wherein the etching step E3 comprises etching with a phosphoric acid solution.

In some embodiments of the present invention, the concentration of silicic acid contained in the phosphoric acid solution is higher than 3.5 ppm.

In some embodiments of the present invention, the temperature of the phosphoric acid solution is between 150 and 160 degrees Celsius.

In some embodiments of the present invention, after the etching step, the etching selectivity of phosphoric acid solution for etching nitride layer and etching oxide layer gradually increases (that is, the concentration of silicic acid gradually increases with the etching times).

In some embodiments of the present invention, after the etching step, an acid concentration adjustment step is further included, a part of the phosphoric acid solution is poured out, and new phosphoric acid solution is added for mixing (that is, new acid needs to be added for blending because the concentration of silicic acid is too high).

In some embodiments of the present invention, after adding new phosphoric acid solution, the etching selectivity ratio of phosphoric acid solution to etching nitride layer and etching oxide layer is reduced.

In some embodiments of the present invention, the rate at which the phosphoric acid solution etches the nitride layer is more than 45 angstroms per minute.

In some embodiments of the present invention, the rate at which the phosphoric acid solution etches the oxide layer is less than 0.15 angstroms per minute.

In some embodiments of the present invention, after the etching step, the surface of the substrate 10 next to the gate structure 16 is slightly lowered, and the lowered height is within 30 angstroms.

In some embodiments of the present invention, a second gate structure (for example, the gate conductive layer of the PMOS gate 12B) is formed next to the gate structure 12A, and the second gate structure 12B includes another oxide layer (the oxide layer 14 of the PMOS gate 12B) and another nitride layer (the first nitride layer 18 of the PMOS gate 12B).

In some embodiments of the present invention, after the etching step E3, the other oxide layer 14 is left and the other nitride layer 18 is removed.

In some embodiments of the present invention, a mask layer (the mask layer 20 of the NMOS gate 12A) is formed on the top surface of gate structure 16, and a second mask layer (the mask layer 20 of the PMOS gate 12B) is formed on the top surface of second gate structure 16, wherein the thickness of the mask layer and the second mask layer are different.

In some embodiments of the present invention, after the etching step E3, both the mask layer (the mask layer 20 of the NMOS gate 12A) and the second mask layer (the mask layer 20 of the PMOS gate 12B) are completely removed.

The invention is characterized by providing an etching method for improving the existing semiconductor structure, especially for the spacer of different gate structures (such as PMOS and NMOS respectively) after the epitaxial layer is formed. In some technologies, dummy spacers are formed to protect the substrate surface in order to avoid damaging the substrate surface when etching the spacers. However, this method has many steps, which is not conducive to simplifying the process. In the invention, by adjusting the etching process and deliberately reducing the etching rate of the oxide material, the etching selectivity ratio for etching the nitride material to the oxide material is increased, so that the step of forming dummy spacers can be omitted and the etching damage to the substrate can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An etching method of a semiconductor structure, comprising:
providing a substrate with a gate structure disposed thereon, an oxide layer and a first nitride layer are disposed beside the gate structure; and
performing an etching step to remove the first nitride layer and keep the oxide layer, wherein in the etching step, the etching selectivity ratio of etching a nitride material to etching an oxide material is greater than 300.

2. The etching method of the semiconductor structure according to claim 1, wherein the oxide layer has a U-shaped cross section and is located at a bottom and two sidewalls of the gate structure.

3. The etching method of the semiconductor structure according to claim 1, further comprising forming a mask layer on a top surface of the gate structure.

4. The etching method of the semiconductor structure according to claim 3, further comprising forming a second nitride layer covering an outer sidewall of the first nitride layer, part of the surface of the substrate and the top surface and sidewall of the mask layer.

5. The etching method of the semiconductor structure according to claim 4, wherein in the etching step, the first nitride layer, the second nitride layer and the mask layer are all removed.

6. The etching method of the semiconductor structure according to claim 4, wherein after the second oxide layer is formed, until the etching step is performed, no other spacers composed of oxide layer or nitride layer are formed.

7. The etching method of the semiconductor structure according to claim 1, wherein the etching step comprises etching with a phosphoric acid solution.

8. The method for etching a semiconductor structure according to claim 7, wherein the concentration of silicic acid contained in the phosphoric acid solution is higher than 3.5 ppm.

9. The etching method of the semiconductor structure according to claim 7, wherein the temperature of the phosphoric acid solution is between 150 and 160 degrees Celsius.

10. The etching method of the semiconductor structure according to claim 7, wherein after the etching step, the etching selectivity of the phosphoric acid solution for etching the nitride material and etching the oxide material gradually increases.

11. The etching method of the semiconductor structure according to claim 7, wherein after the etching step, an acid concentration adjustment step is further performed, a part of the phosphoric acid solution is poured out, and a new phosphoric acid solution is added and mixed.

12. The etching method of the semiconductor structure according to claim 11, wherein after adding the new phosphoric acid solution, the etching selectivity of the phosphoric acid solution for etching the nitride material and etching the oxide material decreases.

13. The etching method of the semiconductor structure according to claim 7, wherein the rate of etching the nitride material by the phosphoric acid solution is more than 45 angstroms per minute.

14. The etching method of the semiconductor structure according to claim 7, wherein the rate of etching the oxide material by the phosphoric acid solution is below 0.15 angstrom per minute.

15. The etching method of the semiconductor structure according to claim 1, wherein after the etching step, the surface of the substrate next to the gate structure is lowered, and the lowered height is within 30 angstroms.

16. The etching method of the semiconductor structure according to claim 1, further comprising forming a second gate structure, which is located next to the gate structure and comprises another oxide layer and another nitride layer.

17. The etching method of the semiconductor structure according to claim 16, wherein after the etching step, the other oxide layer is left and the other nitride layer is removed.

18. The etching method of the semiconductor structure according to claim 16, further comprising forming a mask layer on the top surface of the gate structure and forming a second mask layer on the top surface of the second gate structure, wherein the thickness of the mask layer is different from the thickness of the second mask layer.

19. The etching method of the semiconductor structure according to claim 18, wherein both the mask layer and the second mask layer are completely removed after the etching step.
